(19) United States
(12) Patent Application Publication
(10) Pub. No.: US 2012/0262850 A1
(43) Pub. Date: Oct. 18, 2012

(54) Probe Connector

(76) Inventor: Jui-Pin Lin, New Taipei (TW)

(21) Appl. No.: 13/089,300

(22) Filed: Apr. 18, 2011

(51) Int. Cl. H05K 5/00

(52) U.S. Cl. 361/679.01

(57) ABSTRACT

A probe connector includes a pedestal shell having a barrel and a base pedestal sealing up a bottom of the barrel, a probe pin having a connecting portion movably inserted in the barrel and a touching portion protruding upward from a top of the connecting portion, an elastic element located between the connecting portion and the base pedestal, and a positioning sheath having a sheath body removably coupled to a periphery outside of the top of the barrel. A top edge of the sheath body is shrunk inward to form a ringlike blocking eave with a through hole in the middle thereof. The touching portion passes through the through hole to project upward out of the positioning sheath, and the blocking eave is shrunk inward to overstride a top periphery edge of the barrel to block the connecting portion in the barrel.

### BACKGROUND OF THE INVENTION

1. Field of the Invention

The present invention relates to a connector, and more particularly to a probe connector.

2. The Related Art

Referring to FIG. 1, a traditional probe connector includes a shell 10′, an elastic element 30′ and a probe pin 20′. The shell 10′ has a bottom thereof closed, and a top thereof opened freely. The probe pin 20′ has a base portion 21′ and a touching portion 22′ protruded upward from a middle of a top of the base portion 21′. When assembling the probe connector, the elastic element 30′ and the base portion 21′ of the probe pin 20′ are firstly disposed in the shell 10′ with the touching portion 22′ projecting upward out of the shell 10′, wherein the elastic element 30′ located between the base portion 21′ and the bottom of the shell 10′. Then a periphery edge of the top of the shell 10′ is shrunk inward by an auxiliary jig by means of extrusion-rivet technology to form a blocking eave 11′ which blocks the base portion 21′ in the shell 10′.

However, in the process of assembling the probe connector, there is a process of punching the periphery edge of the top of the shell 10′ inward by means of the extrusion-rivet technology to form the blocking eave 11′ needed. So that is apt to scrape the probe pin 20′ and results in a bad quality of the probe connector. Furthermore, the probe connector has a complicated assembly process and needs higher manufacture cost.

### SUMMARY OF THE INVENTION

An object of the present invention is to provide a probe connector. The probe connector includes a pedestal shell having a hollow barrel of which a bottom is sealed up by a base pedestal and a top is opened freely, an elastic element inserted downward in the barrel with a bottom end thereof resisting against the base pedestal, a probe pin having a connecting portion and a touching portion protruding upward from a substantial middle of a top of the connecting portion, and a positioning sheath. The connecting portion is movably inserted downward in the barrel with a top end of the elastic element abutting against a bottom of the connecting portion. A periphery outside of the connecting portion abuts against a periphery inside of the barrel to realize an electrical connection between the probe pin and the pedestal shell. The positioning sheath has a sheath body with two opposite ends thereof opened freely to make the sheath body removably coupled to a periphery outside of the top of the barrel. A top edge of the sheath body is shrunk inward to form a ringlike blocking eave with a through hole in the middle thereof. The touching portion of the probe pin passes through the through hole to project upward out of the positioning sheath, and the blocking eave is shrunk inward to overstride a top periphery edge of the barrel to block the connecting portion of the probe pin in the barrel.

As described above, the probe connector of the present invention has all components thereof, such as the pedestal shell, the probe pin, the elastic element and the positioning sheath, firstly manufactured respectively. Then the components are assembled together to form the probe connector. So that omits the process of punching a blocking eave by means of extrusion-rivet technology in the process of assembling a traditional probe connector according to the prior art. So the probe connector of the present invention has a simple assembly process. It further assures the quality of the probe connector and effectively reduces the manufacture cost of the probe connector.

### BRIEF DESCRIPTION OF THE DRAWINGS

The present invention will be apparent to those skilled in the art by reading the following description thereof, with reference to the attached drawings, in which:

FIG. 1 is a cross-sectional view of a conventional probe connector;

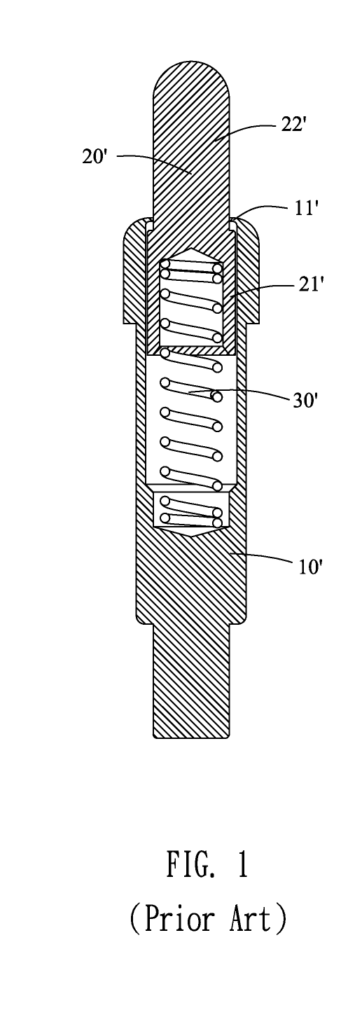

FIG. 2 is an exploded perspective view of a probe connector according to an embodiment of the present invention; and

FIG. 3 is a cross-sectional view of the probe connector of FIG. 2.

### DETAILED DESCRIPTION OF THE PREFERRED EMBODIMENT

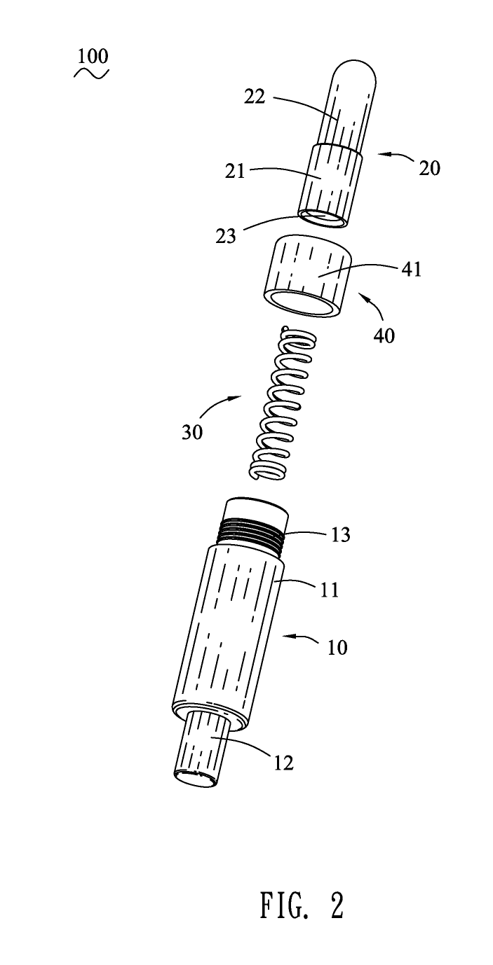

With reference to FIG. 2, a probe connector 100 according to an embodiment of the present invention includes a pedestal shell 10, a probe pin 20, an elastic element 30 and a positioning sheath 40.

The pedestal shell 10 is made of metal material and has a cylindrical and hollow barrel 11 of which a bottom is sealed up by a base pedestal 12 and a top is opened freely. An outside periphery of the top of the barrel 11 is provided with a female screw thread 13 therearound. The probe pin 20 has a cylindrical connecting portion 21 and a touching portion 22 protruding upward from a middle of a top of the connecting portion 21. The connecting portion 21 has an outside diameter corresponding to an inside diameter of the barrel 11, and the touching portion 22 has a diameter smaller than the outside diameter of the connecting portion 21. A bottom of the connecting portion 21 is concaved upward to form a cylindrical receiving chamber 23. In the embodiment, the elastic element 30 is a spring.

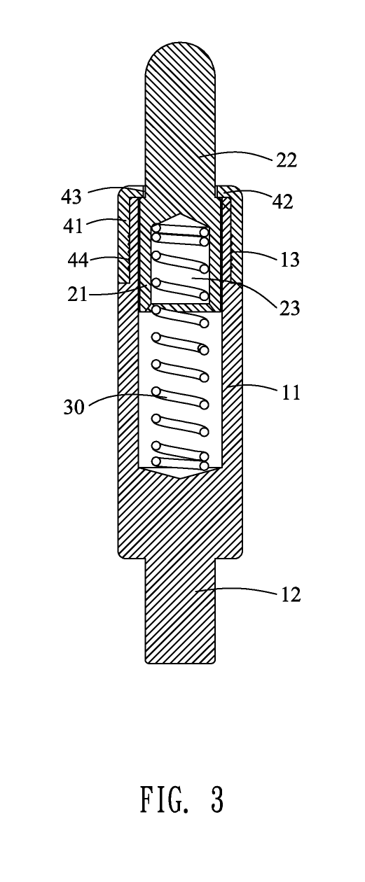

Referring to FIG. 2 and FIG. 3, the positioning sheath 40 is punched from a metal plate and has a substantially cylindrical and hollow sheath body 41. An inside periphery of the sheath body 41 is provided with a male screw thread 44 thereon. A top edge of the sheath body 41 extends inward to form a ringlike blocking eave 42 with a through hole 43 in the middle thereof. The through hole 43 has a diameter smaller than the outside diameter of the connecting portion 21, and corresponding to the one of the touching portion 22.

Referring to FIGS. 2-3 again, when assembling the probe connector 100, the elastic element 30 is inserted downward in the barrel 11 with a bottom end thereof resisting against the base pedestal 12. The connecting portion 21 of the probe pin 20 is movably inserted downward in the barrel 11, with a top end of the elastic element 30 being restrained in the receiving chamber 23. A periphery outside of the connecting portion 21 abuts against a periphery inside of the barrel 11 to realize an electrical connection between the probe pin 20 and the pedestal shell 10. Then the positioning sheath 40 is removably coupled to the top of the barrel 11 by means of the male screw thread 44 engaged with the female screw thread 13. The touching portion 22 of the probe pin 20 passes through the through hole 43 to project upward out of the positioning sheath 40, with the connecting portion 21 being blocked in the barrel 11 by the blocking eave 42.

As described above, the probe connector 100 of the present invention has all components thereof, such as the pedestal shell 10, the probe pin 20, the elastic element 30 and the positioning sheath 40, firstly manufactured respectively. Then the components are assembled together to form the probe connector 100. So that omits the process of punching a blocking eave 11′ by means of extrusion-rivet technology in the process of assembling a traditional probe connector according to the prior art. So the probe connector 100 of the present invention has a simple assembly process. It further assures the quality of the probe connector 100 and effectively reduces the manufacture cost of the probe connector 100.

What is claimed is:

1. A probe connector, comprising:
a pedestal shell having a hollow barrel of which a bottom is sealed up by a base pedestal and a top is opened freely;
an elastic element inserted downward in the barrel with a bottom end thereof resisting against the base pedestal;
a probe pin having a connecting portion and a touching portion protruding upward from a substantial middle of a top of the connecting portion, the connecting portion being movably inserted downward in the barrel with a top end of the elastic element abutting against a bottom of the connecting portion, a periphery outside of the connecting portion abutting against a periphery inside of the barrel to realize an electrical connection between the probe pin and the pedestal shell; and
a positioning sheath having a sheath body with two opposite ends thereof opened freely to make the sheath body removably coupled to a periphery outside of the top of the barrel, a top edge of the sheath body being shrunk inward to form a ringlike blocking eave with a through hole in the middle thereof, the touching portion of the probe pin passing through the through hole to project upward out of the positioning sheath, and the blocking eave being shrunk inward to overstride a top periphery edge of the barrel to block the connecting portion of the probe pin in the barrel.

2. The probe connector as claimed in claim 1, wherein the periphery outside of the top of the barrel is provided with a female screw thread therearound, a periphery inside of the sheath body is provided with a male screw thread thereon, the positioning sheath is removably screwed around the top of the barrel by means of the male screw thread engaged with the female screw thread.

3. The probe connector as claimed in claim 1, wherein the bottom of the connecting portion of the probe pin is concaved upward to form a receiving chamber, the top end of the elastic element is restrained in the receiving chamber.

4. The probe connector as claimed in claim 1, wherein the elastic element is a spring.
